(19) United States
(12) Patent Application Publication
(10) Pub. No.: US 2025/0113489 A1
(43) Pub. Date: Apr. 3, 2025

(54) GERMANIUM-DOPED CHARGE TRAPPING LAYER, RELATED DEVICES, RELATED SYSTEMS, AND RELATED METHODS

(71) Applicant: ASM IP Holding B.V., Almere (NL)

(72) Inventors: Ranjith Karuparambil Ramachandran, Leuven (BE); Vivek Koladi Mootheri, Leuven (BE); Andrea IIliberi, Leuven (BE); Charles Dezelah, Helsinki (FI)

(21) Appl. No.: 18/903,866

(22) Filed: Oct. 1, 2024

Related U.S. Application Data
(60) Provisional application No. 63/587,301, filed on Oct. 2, 2023.

(51) Int. Cl. H10B 43/30; H01L 29/167; H10B 41/20; H10B 41/30

(52) U.S. Cl. CPC H10B 43/30; H10B 41/20; H10B 41/30; H10D 62/834

(57) ABSTRACT

Aspects of the disclosure generally relate to the field of semiconductor devices, and more particularly, a memory element comprising a charge trapping layer and systems and methods for producing the same. The method for forming a charge trapping layer of a memory element, comprises the steps of: providing a substrate into a reaction chamber; executing one or more cycles, a cycle comprising a hafnium precursor pulse; optionally, a zirconium precursor pulse; an oxygen reactant pulse; a germanium dopant pulse; and wherein, as a result of the one or more cycles, a charge trapping layer comprising one or more germanium-doped hafnium oxide (HfO₂) film and/or one or more germanium-doped hafnium zirconium oxide (HZO) film is formed on the substrate.

### CROSS-REFERENCE TO RELATED APPLICATION(S)

This application claims the benefit of U.S. Provisional Application 63/587,301 filed on Oct. 2, 2023, the entire contents of which are incorporated herein by reference.

### FIELD OF INVENTION

The present disclosure generally relates to the field of semiconductor devices. More particularly, a germanium-doped charge trapping layer of a memory element, and methods and systems for producing the same.

### BACKGROUND OF THE DISCLOSURE

Charge trapping layers comprised within a memory element are essential components for data storage and retrieval, but can also pose different challenges that impact device performance and reliability. These issues arise from the complex interplay of material properties, electrical characteristics, and operational conditions. Some of the problems associated with charge trapping layers include inherent manufacturing variation, gradual deterioration during use, and charge leakage. Especially the ongoing scaling of semiconductor devices, such as, for example, memory elements, has increased the charge leakage problem, wherein trapped charges escape the insulator layer over time. Less effective trapping and releasing of charges has an important impact on the writing and erasing efficiency of the memory device (e.g. a flash memory). Moreover, for closely packed high-density memory arrays, crosstalk and disturb effects can be observed due to unwanted charge transfers of an operating memory cell to neighboring memory cells, leading to erroneous data reads or data modification. Therefore, a need exists to improve the manufacturing of memory elements comprising charge trapping layers to avoid the aforementioned problems, such as charge leakage, and obtain consistent and reliable semiconductor devices.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In general, the technology disclosed herein relates to the field of semiconductor devices, and more specifically to a method for forming a charge retention or capturing medium of a memory element used in the production of several electronic components such as non-volatile memory technology and memory chips including NAND flash drives and solid state drives (SSD).

An aspect of the present disclosure relates to a method for forming a charge trapping layer of a memory element, comprising the steps of:
a) providing a substrate into a reaction chamber;
b) executing a plurality of cycles, a cycle comprising
   i. a hafnium precursor pulse, wherein at least a part of said substrate is contacted with one or more hafnium precursor by introducing said one or more hafnium precursor in said reaction chamber;
   ii. optionally, a zirconium precursor pulse, wherein at least a part of said substrate is contacted with one or more zirconium precursor by introducing said one or more zirconium precursor in said reaction chamber;
   iii. an oxygen reactant pulse, wherein at least a part of said substrate is contacted with one or more oxygen reactant by introducing said one or more oxygen reactant into said reaction chamber;
   iv. a germanium dopant pulse, wherein at least a part of said substrate is contacted with one or more germanium dopant by introducing said one or more germanium dopant into said reaction chamber; and
      wherein, as a result of said plurality of cycles, a charge trapping layer comprising one or more germanium-doped hafnium zirconium oxide (HZO) film is formed on said substrate.

The herein disclosed method relates to a deposition process wherein one or more metal oxide film is grown by exposing the surface of a substrate to a sequence of alternating precursors, reactants, and dopants. The one or more doped metal oxide film can subsequently be used to trap or store electrical charges, which corresponds to stored data in an electrical device. Advantageously, the present inventors have found that the herein disclosed methods and devices may allow to form charge trapping films or layers with decreased variations in layer thickness, and defects, resulting in improved memory devices. To elaborate, the herein disclosed methods operate via controlled deposition pulses of precursors, reactants, and other components to control the growth rate and composition of the formed metal oxide layers. Moreover, amongst one of said pulses is a dopant pulse that can induce controlled doping of the formed metal oxide layers, resulting in good electrical characteristics, while promoting stable and reliable memory element operation. In particular, one of the advantages of the present disclosure can be a reduction in charge leakage of the charge trap layer even at significantly reduced device dimensions, enabling more reliable data storage.

In a particular embodiment, the method as disclosed herein provides that the method is an atomic layer deposition (ALD) method. It has been found that ALD offers several advantages over traditional sputtering techniques when it comes to thin film deposition such as precise layer thickness control, uniform deposition, and controlled film composition, allowing the formation of alloys and oxides with high material purity. Especially for structures with high aspect ratios (e.g., deep trenches or high-porosity materials), it has been found that ALD can achieve uniform and conformal film deposition, which was proven challenging with other deposition techniques disclosed in the state of the art.

In a particular embodiment, the method as disclosed herein provides that said charge trapping layer is formed without any intervening vacuum break. It has been found that the herein disclosed method allows for continuous or in-situ deposition of material to grow a thin film, resulting in enhanced film quality, higher efficiency and reduced risk of contamination.

An overview of various aspects of the technology of the present disclosure is provided herein below, followed by a detailed description of specific embodiments. It should be understood that the objectives and advantages mentioned above apply equally to the various aspects and features as disclosed herein.

Another aspect of the present disclosure relates to a system comprising:
a reaction chamber constructed and arranged to hold a substrate;
a hafnium precursor vessel constructed and arranged to contain and evaporate one or more hafnium precursor;
a zirconium precursor vessel constructed and arranged to contain and evaporate one or more zirconium precursor;
an oxygen reactant vessel constructed and arranged to contain and evaporate one or more oxygen reactant;
a germanium dopant vessel constructed and arranged to contain and evaporate one or more germanium dopant;
a controller, operatively connected to the hafnium precursor vessel, the zirconium precursor vessel, the oxygen reactant vessel, and the germanium dopant vessel;
wherein the controller is configured to control the introduction of said one or more hafnium precursor, said one or more zirconium precursor, said one or more oxygen reactant, and said one or more germanium dopant into the reaction chamber during a plurality of cycles, wherein, as a result of the plurality of cycles, a charge trapping layer comprising one or more germanium-doped HZO film is formed on the substrate.

In a particular embodiment, the system as disclosed herein is configured to form a charge trapping layer of a memory element by means of a method as disclosed herein.

Another aspect of the present disclosure relates to a memory element comprising:
a gate electrode;
a blocking dielectric, the blocking dielectric being adjacent to the gate electrode;
a tunnel dielectric;
a charge trapping layer, the charge trapping layer being positioned between the blocking dielectric and the tunnel dielectric;
an n-type layer, the n-type layer being adjacent to the tunnel dielectric; and
a p-type layer, the p-type layer being adjacent to the n-type layer;
wherein said charge trapping layer is obtained by means of a method as disclosed herein.

Another aspect of the present disclosure relates to a memory element comprising:
a gate electrode;
a blocking dielectric, the blocking dielectric being adjacent to the gate electrode;
a tunnel dielectric;
a charge trapping layer, the charge trapping layer being positioned between the blocking dielectric and the tunnel dielectric;
an n-type layer, the n-type layer being adjacent to the tunnel dielectric; and
a p-type layer, the p-type layer being adjacent to the n-type layer;
wherein said charge trapping layer comprises one or more germanium-doped hafnium HZO layer.
Another aspect of the present disclosure relates to a gate stacked 3D NAND memory comprising
a vertical channel and a plurality of floating gate stacks, the floating gate stacks each comprising a tunnel dielectric adjacent to the vertical channel, a charge trapping layer adjacent to the tunnel dielectric, a blocking dielectric adjacent to the charge trapping layer, and a gate electrode adjacent to the blocking dielectric; wherein said charge trapping layer comprises one or more germanium-doped HZO layer.

In a particular embodiment, the gate stacked 3D NAND memory as disclosed herein provides that said charge trapping layer is obtained by means of a method as disclosed herein. In a particular embodiment, the gate stacked 3D NAND memory as disclosed herein further comprises a memory element as disclosed herein.

In another aspect, the present disclosure relates to the use of of a germanium precursor for increasing the charge trap and decreasing the charge loss rate of charge trap layers in a semiconductor structure.

### DESCRIPTION OF THE FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 schematically illustrates an exemplary embodiment of a method for forming a charge trapping layer of a memory element comprising a doped HfO₂ layer as disclosed herein.

FIG. 2 schematically illustrates another exemplary embodiment of a method for forming a charge trapping layer of a memory element comprising a doped HfO₂ layer as disclosed herein.

FIG. 3 schematically illustrates another exemplary embodiment of a method for forming a charge trapping layer of a memory element comprising a doped HZO layer as disclosed herein.

FIG. 4 schematically illustrates another exemplary embodiment of a method for forming a charge trapping layer of a memory element comprising a doped HZO layer as disclosed herein.

FIG. 5 schematically illustrates another exemplary embodiment of a method for forming a charge trapping layer of a memory element comprising a doped HZO layer and a doped HfO₂ layer as disclosed herein.

FIG. 6 schematically illustrates a system (600) in accordance with yet additional exemplary embodiments of the disclosure.

### DETAILED DESCRIPTION OF EXEMPLARY EMBODIMENTS

Although certain embodiments and examples are disclosed below, it will be understood by those in the art that the present disclosure extends beyond the specifically disclosed embodiments and/or uses of the present disclosure and obvious modifications and equivalents thereof. Thus, it is intended that the scope of the present disclosure disclosed should not be limited by the particular disclosed embodiments described below.

In the following detailed description, the technology underlying the present disclosure will be described by means of different aspects thereof. It will be readily understood that the aspects of the present disclosure, as generally described herein, and illustrated in the figures, can be arranged, substituted, combined, and designed in a wide variety of different configurations, all of which are explicitly contemplated and make part of this disclosure. This description is meant to aid the reader in understanding the technological concepts more easily, but it is not meant to limit the scope of the present disclosure, which is limited only by the claims.

Reference throughout this specification to “one embodiment” or “an embodiment” means that a particular feature, structure or characteristic described in connection with the embodiment is included in at least one embodiment of the present disclosure. Thus, appearances of the phrases “in one embodiment” or “in an embodiment” in various places throughout this specification are not necessarily all referring to the same embodiment.

As used herein, the terms “comprising”, “comprises” and “comprised of” as used herein are synonymous with “including”, “includes” or “containing”, “contains”, and are inclusive or open-ended and do not exclude additional, non-recited members, elements or method steps. The terms “comprising”, “comprises” and “comprised of” when referring to recited members, elements or method steps also include embodiments which “consist of” the recited members, elements or method steps. The singular forms “a”, “an”, and “the” include both singular and plural referents unless the context clearly dictates otherwise.

Objects described herein as being “connected” or “coupled” reflect a functional relationship between the described objects, that is, the terms indicate the described objects must be connected in a way to perform a designated function which may be a direct or indirect connection in an electrical or nonelectrical (i.e. physical) manner, as appropriate for the context in which the term is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, the term “about” is used to provide flexibility to a numerical value or range endpoint by providing that a given value may be “a little above” or “a little below” the value or endpoint, depending on the specific context. Unless otherwise stated, use of the term “about” in accordance with a specific number or numerical range should also be understood to provide support for such numerical terms or range without the term “about”. For example, the recitation of “about 30” should be construed as not only providing support for values a little above and a little below 30, but also for the actual numerical value of 30 as well.

The recitation of numerical ranges by endpoints includes all integer numbers and, where appropriate, fractions subsumed within that range (e.g., 1 to 5 can include 1, 2, 3, 4 when referring to, for example, a number of elements, and can also include 1.5, 2, 2.75 and 3.80, when referring to, for example, measurements). The recitation of end points also includes the end point values themselves (e.g., from 1.0 to 5.0 includes both 1.0 and 5.0). Any numerical range recited herein is intended to include all sub-ranges subsumed therein. Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the disclosure described herein are capable of operation in other sequences than described or illustrated herein.

Reference in this specification may be made to devices, structures, systems, or methods that provide “improved” performance (e.g. increased or decreased results, depending on the context). It is to be understood that unless otherwise stated, such “improvement” is a measure of a benefit obtained based on a comparison to devices, structures, systems or methods in the prior art. Furthermore, it is to be understood that the degree of improved performance may vary between disclosed embodiments and that no equality or consistency in the amount, degree, or realization of improved performance is to be assumed as universally applicable.

In addition, embodiments of the present disclosure may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic based aspects of the present disclosure may be implemented in software (e.g., instructions stored on non-transitory computer-readable medium) executable by one or more processing units, such as a microprocessor and/or application specific integrated circuits. As such, it should be noted that a plurality of hardware and software-based devices, as well as a plurality of different structural components may be utilized to implement the technology of the present disclosure. For example, “servers” and “computing devices” described in the specification can include one or more processing units, one or more computer-readable medium modules, one or more input/output interfaces, and various connections connecting the components.

Reference throughout this specification to substituents is meant to indicate that one or more hydrogen atoms on the atom indicated in the expression using “substituted” is replaced with a selection from an indicated group as detailed below, provided that the indicated atom's normal valence is not exceeded, and that the substitution results in a chemically stable compound, i.e. a compound that is sufficiently robust to survive isolation from a reaction mixture.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, particularly a compound that constitutes a film matrix or a main skeleton of a film; the term “reactant” can be used interchangeably with the term precursor.

In this disclosure, the following abbreviations of chemical structures are used: Cp stands for cyclopentadienyl, Me stands for methyl; Et stands for ethyl; n-Pr stands for n-propyl; i-Pr stands for i-propyl or isopropyl, n-Bu stands for n-butyl; t-Bu stands for t-butyl or tert-butyl.

In the present description, technology is described by means of which a charge trapping or charge retention material can be produced that is suitable for the manufacturing of a memory element or device. More specifically, various embodiments of the present disclosure relate to a thin-film deposition method for forming a charge trapping layer of a memory element, comprising the steps of:
a) providing a substrate into a reaction chamber;
b) executing one or more cycles, a cycle comprising
i. a hafnium precursor pulse, wherein at least a part of said substrate is contacted with one or more hafnium precursor by introducing said one or more hafnium precursor in said reaction chamber;
ii. optionally, a zirconium precursor pulse, wherein at least a part of said substrate is contacted with one or more zirconium precursor by introducing said one or more zirconium precursor in said reaction chamber;
iii. an oxygen reactant pulse, wherein at least a part of said substrate is contacted with one or more oxygen reactant by introducing said one or more oxygen reactant into said reaction chamber;
iv. a germanium dopant pulse, wherein at least a part of said substrate is contacted with one or more germanium dopant by introducing said one or more germanium dopant into said reaction chamber; and
wherein, as a result of said one or more cycles, a charge trapping layer comprising one or more germanium-doped hafnium oxide (HfO₂) film and/or one or more germanium-doped hafnium zirconium oxide (HZO) film is formed on said substrate.
In a particular embodiment, the method as disclosed herein provides that as a result of said one or more cycles, a charge trapping layer comprising one or more germanium-doped hafnium oxide (HfO₂) film and one or more germanium-doped hafnium zirconium oxide (HZO) film is formed on said substrate.

In a particular embodiment, the method as disclosed herein provides that said one or more cycles are a plurality of cycles.

A “memory element” as referred to herein involves an electronic component or device capable of storing, retaining, and retrieving digital information or data. It typically consists of one or more storage cells, each of which can represent a discrete unit of data, often in the form of binary states (0 or 1). In a memory element, data storage and retrieval are facilitated through controlled manipulation of the physical state of the storage cells. These states are typically defined by distinct electrical, optical, or magnetic properties, which can be altered through appropriate input signals. In a memory element utilizing charge trapping, the core concept involves manipulating the charge state of specialized regions, referred to as “charge trapping layers”, within the device's structure. The term “charge trapping layer” as used herein, may refer to a film or layer as defined herein below arranged or situated between insulating materials and semiconductor materials, creating a structure that can trap and hold charges for extended periods of time. Once charges are trapped in the charge trapping layer, they remain stored within the traps until a specific operation (such as erasing or reading) is performed.

Hence, the herein disclosed method involves the growth of a thin-film or layer with specific charge retention properties. A “film” or “layer” as referred to herein may be any continuous or non-continuous structure and material, such as material deposited according to the present technology. For example, a film and/or layer can include two-dimensional materials, three-dimensional materials, nanoparticles or even partial or full molecular layers or partial or full atomic layers or clusters of atoms and/or molecules, or layers consisting of isolated atoms and/or molecules. A film or layer may comprise material or a layer with pinholes, which may or may not be continuous.

During the method as disclosed herein, the surface of a substrate is exposed to various precursors, reactants and germanium dopants to form a charge trapping layer comprising one or more germanium-doped metal oxide film. As used herein, the term “substrate” can refer to any underlying material or materials that can be used to form, or upon which, a device, a circuit, or a film can be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or (high-k) dielectric material layer overlying at least a portion of the bulk semiconductor material. In particular embodiments, the substrate may comprise silicon, silicon germanium, silicon oxide, gallium arsenide, gallium nitride or silicon carbide. A continuous substrate may extend beyond the bounds of a process/reaction chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of a continuous substrate may include a sheet or a flexible material. Continuous substrates may also comprise carriers or sheets upon which non-continuous substrates are mounted.

In particular embodiments, the charge trapping layer comprises one or more germanium-doped HfO₂ film. In particular embodiments, the charge trapping layer comprises one or more germanium-doped HZO film. In some embodiments, the charge trapping layer comprises one or more germanium-doped HfO₂ film and one or more germanium-doped HZO film. Advantageously, the herein disclosed method may allow the controlled deposition, construction, and formation of a charge trapping layer with a decreased number of defects, uniform layer thickness, and targeted doping, resulting in an increased charge trap efficiency and decreased charge loss rate.

In particular, the formation of a charge trapping layer comprising one or more germanium-doped HfO₂ film and/or one or more germanium-doped HZO film on a substrate as described herein may relate to a cyclical deposition process, such as an atomic layer deposition (ALD) process or a cyclical chemical vapor deposition (CVD) process. The cyclical deposition process may comprise one or more cycles. In particular embodiments, the method as disclosed herein is an ALD method. In contrast to sputtering techniques commonly used within the state of the art for deposition of thin films and layers in various semiconductor and memory element processes, cyclical deposition processes such as ALD were found to provide more uniform deposition across the surface of the substrate.

As used herein, the synonymous terms “deposition” or “cyclic deposition” or “cyclic deposition process” or “cyclical deposition process” refer to a sequential introduction of precursors (and/or reactants) into a reaction chamber to deposit a layer or film over a substrate and includes processing techniques such as ALD, CVD, and hybrid cyclical deposition processes that include an ALD component and a CVD component. Typically, one deposition cycle may form a film or layer of about 0.10 nm. However, the experimental thickness may vary depending on the amount and type of cycles and available reaction sites on the substrate.

The term “atomic layer deposition” or “ALD” refers to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a precursor (e.g. a hafnium precursor and/or a zirconium precursor) is introduced to a reaction chamber and is chemisorbed to a deposition surface (e.g., a substrate surface that can include a previously deposited material from a previous ALD cycle or other material) and forming material, e.g. about a monolayer or sub-monolayer of material, or several monolayers of material, or a plurality of monolayers of material, that does not readily react with additional precursor (i.e., a self-limiting reaction). Thereafter, in some cases, a reactant (e.g., another precursor or reaction gas such as an oxygen reactant) may subsequently be introduced into the process chamber for use in converting the chemisorbed precursor to the desired material on the deposition surface. The reactant can be capable of further reaction with the precursor. Purging steps can be utilized during one or more repetitions, e.g. during each deposition step, to remove any excess precursor from the process chamber and/or remove any excess reactant and/or reaction byproducts from the reaction chamber. Note that, in several embodiments as described herein, ALD processes are not necessarily comprised of a sequence of self-limiting surface reactions.

As used herein, the term “purge” may refer to a procedure in which an inert or substantially inert gas is provided to a reaction chamber in between two pulses of gasses that react with each other. For example, a purge, e.g. using an inert gas such as a noble gas, may be provided between a precursor pulse and a reactant pulse, thus avoiding or at least minimizing gas phase interactions between the precursor and the reactant.

Advantageously, a cyclical deposition process as disclosed herein can be a thermal deposition process. In other words, in some embodiments, none of the pulses or purges in the cyclical deposition process employs a plasma. In the case of thermal cyclical deposition processes, a duration of the step of providing the hafnium precursor and/or zirconium precursor to the reaction chamber, a duration of the step of providing the reactant to the reaction chamber, and/or a duration of the step of providing the germanium dopant to the reaction chamber can be relatively long to allow the precursors, reactants, and/or dopants containing gas to react with a surface of the substrate. For example, the duration can be greater than or equal to 5 seconds or greater than or equal to 10 seconds or between about 5 and 10 seconds.

In some embodiments, the cyclical deposition process employs a plasma-enhanced deposition technology. For example, the cyclical deposition process may comprise a plasma-enhanced atomic layer deposition process and/or a plasma-enhanced chemical vapor deposition process. In such a case, any one of the pulses in the cyclical depositing process may comprise generating a plasma in the reaction chamber.

In some embodiments, the method as disclosed herein may be a continuous vacuum deposition process. In the context of a continuous vacuum deposition process, a material is deposited onto a substrate in a reaction chamber without the introduction of atmospheric air or any interruptions that would break the controlled vacuum environment. This process involves maintaining a consistent vacuum pressure within the reaction chamber. In particular embodiments, the method as disclosed herein provides that the charge trapping layer is formed without any intervening vacuum break. This has the advantage that the present disclosure avoids the need for repeated evacuations and purges of the reaction chamber that are common in traditional batch deposition methods.

In particular embodiments, the method as disclosed herein comprises at least 1 cycle, at least 2 cycles, at least 5 cycles, at least 10 cycles, at least 20 cycles, at least 40 cycles, at least 100 cycles, at least 200 cycles, at least 400 cycles, at least 600 cycles, at least 1000 cycles. In some embodiments, the steps may be repeated from at least 1 cycle to at most 1000 cycles, or from at least 2 cycles to at most 100 cycles, or from at least 5 cycles to at most 50 cycles.

In particular embodiments, the method as disclosed herein provides that the formed one or more germanium-doped HfO₂ film and/or one or more germanium-doped HZO film may have an average thickness between 0.10 nm and 30.0 nm, or between 0.10 nm and 20.0 nm, preferably between 0.50 nm and 20.0 nm, or between 1.0 nm and 20.0 nm, or between 1.0 nm and 15.0 nm, or more preferably between 1.0 nm and 10.0 nm, even more preferably between 1.0 nm and 5.0 nm. In some embodiments, the one or more germanium-doped HfO₂ film and/or one or more germanium-doped HZO film may have an average thickness of less than 1.0 nm, such as less than 0.50 nm, such as about 0.10 nm.

It shall be understood that when a HfO₂ film and/or a HZO film is deposited on the substrate, intermixing of those layer's constituent components may occur to some extent. For example, when a HZO layer is deposited on a HfO₂ layer, at least one of hafnium, zirconium, or oxygen may be incorporated in the hafnium oxide containing layer, for example by means of diffusion, surface segregation, or another process. For example, when a HZO layer is deposited on a substrate comprising silicon oxide, at least one of silicon or oxide may be incorporated in the hafnium zirconium oxide containing layer. In some embodiments, such intermixing can result in the formation of an interlayer containing both components of each layer. Moreover, the extremely thin HfO₂ film and/or HZO film may further comprise hydrogen and/or carbon in the resulting charge trapping layer.

In some embodiments, the one or more germanium-doped HfO₂ film and/or one or more germanium-doped HZO film may have a growth rate of 0.10 nm or less per cycle of precursor(s)/reactive gas(es), and purge (e.g., inert carrier) gas(es). A layer of lower thickness may be desirable for many electronics applications, including memory elements for high-density data storage.

The method as disclosed herein relies on the execution of one or more cycles to grow a thin-film charge trap. A cycle as referred herein comprises three or more pulses. In some embodiments, at least one pulse involves a self-limiting surface reaction. In some embodiments, all pulses involve a self-limiting surface reaction. In some embodiments, a cycle may comprise the following sequence of pulses: a hafnium precursor pulse, an oxygen reactant pulse, and a germanium dopant pulse. In some embodiments, a cycle may comprise the following sequence of pulses: a hafnium precursor pulse, a zirconium precursor pulse, an oxygen reactant pulse, and a germanium dopant pulse. In the hafnium precursor pulse, one or more hafnium precursor is provided into the reaction chamber and may chemisorb to the substrate (i.e., adheres and forms chemical bonds with atoms or molecules on the surface of said substrate). In the zirconium precursor pulse, one or more zirconium precursor is provided into the reaction chamber and may chemisorb to the substrate. In the oxygen reactant pulse, the one or more oxygen reactant is provided into the reaction chamber and may react with the chemisorbed hafnium metal and/or zirconium metal to form a metal oxide film or layer on at least a part of the substrate (e.g. Hafnium Oxide (HfO₂) and/or Hafnium Zirconium Oxide (HfZrO₂)). In the germanium dopant pulse, one or more germanium dopant is provided into the reaction chamber and may adhere to the surface of the deposited metal oxide film or layer and may react to incorporate germanium dopant atoms or molecules into the growing layer. The number of cycles of the method as disclosed herein determines the overall thickness of the deposited HfO₂ film and/or the HZO film and the germanium dopant concentration within it. An advantage of the presently disclosed cyclical deposition process is the precise control over said overall layer thickness and dopant incorporation.

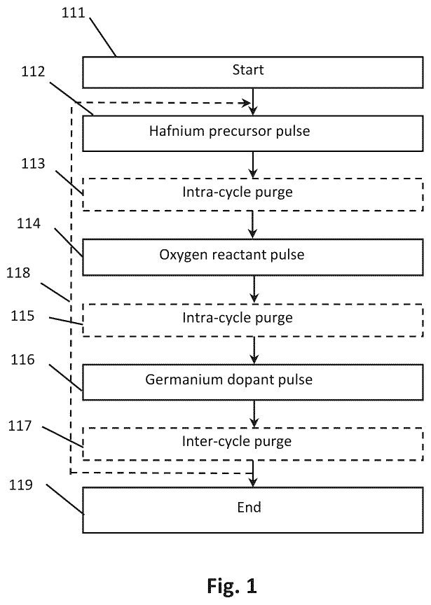

FIG. 1. describes an exemplary embodiment of the method as described herein for forming a charge trapping layer comprising one or more germanium-doped Hf)₂ film as disclosed herein. The method starts (111) after a substrate has been provided to a reaction chamber. The cyclical deposition process comprises contacting one or more hafnium precursor with at least a part of the substrate in a hafnium precursor pulse (112). Optionally, the reaction chamber is purged (113) after the hafnium precursor pulse (112). Then, one or more oxygen reactant is provided to the reaction chamber in an oxygen reactant pulse (114). Optionally, the reaction chamber can be purged (115) after the oxygen reactant pulse. Then, one or more germanium dopant is provided to the reaction chamber in a germanium dopant pulse (116). Optionally, the reaction chamber can be purged (117) after the germanium dopant pulse.

The hafnium precursor pulse (112), the oxygen reactant pulse (114), the germanium dopant pulse (116), and the optional purges (113,115,117) can be repeated (118) any number of times to obtain
a charge trapping layer comprising one or more germanium-doped HfO₂ film having a desired thickness. When a charge trapping layer comprising one or more germanium-doped HfO₂ film having a desired thickness has been deposited, the method ends (119). Once the method has ended, the substrate can, for example, be subjected to additional processes to form a device structure and/or device.

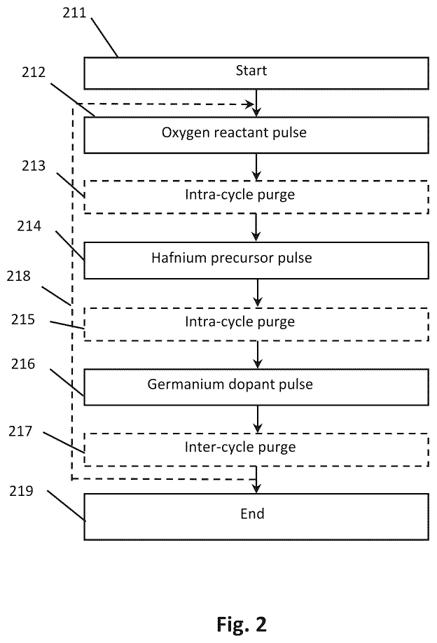

FIG. 2. describes another exemplary embodiment of the method as described herein for forming a charge trapping layer comprising one or more germanium-doped HfO₂ film as disclosed herein. The method starts (211) after a substrate has been provided to a reaction chamber. The cyclical deposition process comprises providing one or more oxygen reactant to the reaction chamber in an oxygen reactant pulse (212). Optionally, the reaction chamber is purged (213) after the oxygen reactant pulse (212). Then, at least a part of the substrate is contacted with one or more hafnium precursor in a hafnium precursor pulse (214). Optionally, the reaction chamber is purged (215) after the hafnium precursor pulse. Then, one or more germanium dopant is provided to the reaction chamber in a germanium dopant pulse (216). Optionally, the reaction chamber can be purged (217) after the germanium dopant pulse. The oxygen reactant pulse (212), the hafnium precursor pulse (214), the germanium dopant pulse (216), and the optional purges (213,215,217) can be repeated (218) any number of times to obtain a charge trapping layer comprising one or more germanium-doped HfO₂ film having a desired thickness. When a charge trapping layer comprising one or more germanium-doped HfO₂ film having a desired thickness has been deposited, the method ends (219). Once the method has ended, the substrate can, for example, be subjected to additional processes to form a device structure and/or device.

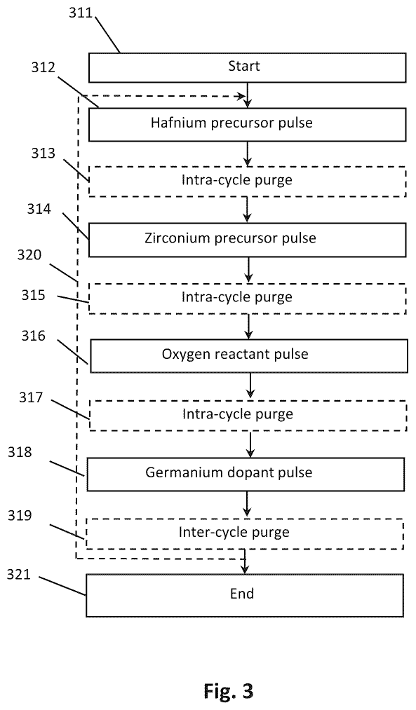

FIG. 3. describes another exemplary embodiment of the method as described herein for forming a charge trapping layer comprising one or more germanium-doped HZO film as disclosed herein. The method starts (311) after a substrate has been provided to a reaction chamber. The cyclical deposition process comprises contacting one or more hafnium precursor with at least a part of the substrate in a hafnium precursor pulse (312). Optionally, the reaction chamber is purged (313) after the hafnium precursor pulse (312). Then, at least a part of the substrate is contacted with one or more zirconium precursor in a zirconium precursor pulse (314). Optionally, the reaction chamber is purged (315) after the zirconium precursor pulse. Then, one or more oxygen reactant is provided to the reaction chamber in an oxygen reactant pulse (316). Optionally, the reaction chamber can be purged (317) after the oxygen reactant pulse. Then, one or more germanium dopant is provided to the reaction chamber in a germanium dopant pulse (318). Optionally, the reaction chamber can be purged (319) after the germanium dopant pulse. The hafnium precursor pulse (312), the zirconium precursor pulse (314), the oxygen reactant pulse (316), the germanium dopant pulse (318), and the optional purges (313,315,317,319) can be repeated (320) any number of times to obtain a charge trapping layer comprising one or more germanium-doped HZO film having a desired thickness. When a charge trapping layer comprising one or more germanium-doped HZO film having a desired thickness has been deposited, the method ends (321). Once the method has ended, the substrate can, for example, be subjected to additional processes to form a device structure and/or device.

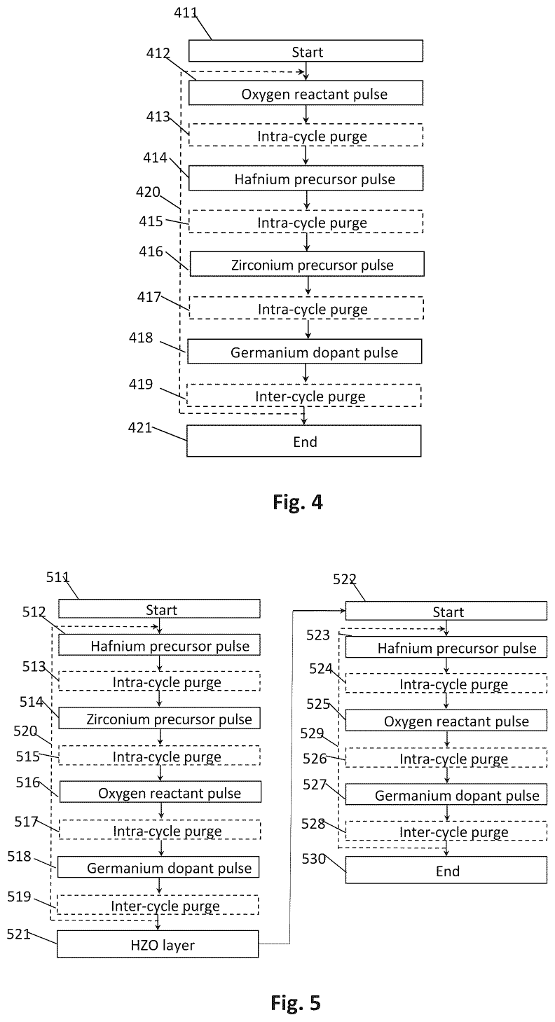

FIG. 4. describes another exemplary embodiment of the method as described herein for forming a charge trapping layer comprising one or more germanium-doped HZO film as disclosed herein. The method starts (411) after a substrate has been provided to a reaction chamber. The cyclical deposition process comprises providing one or more oxygen reactant to the reaction chamber in an oxygen reactant pulse (412). Optionally, the reaction chamber can be purged (413) after the oxygen reactant pulse (412). Then, at least a part of the substrate is contacted with one or more hafnium precursor in a hafnium precursor pulse (414). Optionally, the reaction chamber is purged (415) after the hafnium precursor pulse. Then, at least a part of the substrate is contacted with one or more zirconium precursor in a zirconium precursor pulse (416). Optionally, the reaction chamber is purged (417) after the zirconium precursor pulse. Then, one or more germanium dopant is provided to the reaction chamber in a germanium dopant pulse (418). Optionally, the reaction chamber can be purged (419) after the germanium dopant pulse. The oxygen reactant pulse (412), the hafnium precursor pulse (414), the zirconium precursor pulse (416), the germanium dopant pulse (418), and the optional purges (413,415,417,419) can be repeated (420) any number of times to obtain a charge trapping layer comprising one or more germanium-doped HZO film having a desired thickness. When a charge trapping layer comprising one or more germanium-doped HZO film having a desired thickness has been deposited, the method ends (421). Once the method has ended, the substrate can, for example, be subjected to additional processes to form a device structure and/or device.

FIG. 5. describes another exemplary embodiment of the method as described herein for forming a charge trapping layer comprising one or more germanium-doped HZO film and one or more germanium-doped HfO₂ film as disclosed herein. The method starts (511) after a substrate has been provided to a reaction chamber. The cyclical deposition process comprises contacting one or more hafnium precursor with at least a part of the substrate in a hafnium precursor pulse (512). Optionally, the reaction chamber is purged (513) after the hafnium precursor pulse (512). Then, at least a part of the substrate is contacted with one or more zirconium precursor in a zirconium precursor pulse (514). Optionally, the reaction chamber is purged (515) after the zirconium precursor pulse. Then, one or more oxygen reactant is provided to the reaction chamber in an oxygen reactant pulse (516). Optionally, the reaction chamber can be purged (517) after the oxygen reactant pulse. Then, one or more germanium dopant is provided to the reaction chamber in a germanium dopant pulse (518). Optionally, the reaction chamber can be purged (519) after the germanium dopant pulse.

The hafnium precursor pulse (512), the zirconium precursor pulse (514), the oxygen reactant pulse (516), the germanium dopant pulse (518), and the optional purges (513,515,517,519) can be repeated (520) any number of times to obtain a charge trapping layer comprising one or more germanium-doped HZO film having a desired thickness. When a charge trapping layer comprising one or more germanium-doped HZO film having a desired thickness has been deposited (521), the method continues to form the one or more germanium-doped HfO₂ film as disclosed herein. The second part of the method starts (522) after the substrate has been provided to the same reaction chamber or a different reaction chamber. The cyclical deposition process comprises contacting one or more hafnium precursor with at least a part of the substrate in a hafnium precursor pulse (523). Optionally, the reaction chamber is purged (524) after the hafnium precursor pulse (523). Then, one or more oxygen reactant is provided to the reaction chamber in an oxygen reactant pulse (525). Optionally, the reaction chamber can be purged (526) after the oxygen reactant pulse. Then, one or more germanium dopant is provided to the reaction chamber in a germanium dopant pulse (527). Optionally, the reaction chamber can be purged (528) after the germanium dopant pulse.

The hafnium precursor pulse (523), the oxygen reactant pulse (525), the germanium dopant pulse (527), and the optional purges (524,526,528) can be repeated (529) any number of times to obtain
a charge trapping layer comprising one or more germanium-doped HfO₂ film having a desired thickness. When a charge trapping layer comprising one or more germanium-doped HfO₂ film having a desired thickness has been deposited, the method ends (530). Once the method has ended, the substrate can, for example, be subjected to additional processes to form a device structure and/or device.

As illustrated in FIG. 1 to FIG. 5, in some embodiments, a cycle comprises a sequence of a hafnium precursor pulse, optionally a zirconium precursor pulse, an oxygen reactant pulse, and a germanium dopant pulse. In some embodiments, the method as disclosed herein comprises a number of cycles, wherein the sequence of consecutive pulses within each cycle may vary. For instance, an oxygen reactant pulse may precede a hafnium precursor pulse and/or a zirconium precursor pulse. In particular embodiments, the method as disclosed herein provides that an oxygen reactant pulse is carried out after each hafnium precursor pulse and/or after each zirconium precursor pulse. In particular embodiments, the method as disclosed herein provides that the germanium dopant pulse is carried out after the hafnium precursor pulse without any intervening oxygen reactant pulse. In particular embodiments, the method as disclosed herein provides that the germanium dopant pulse is carried out after the zirconium precursor pulse without any intervening oxygen reactant pulse.

In particular embodiments, the method as disclosed herein provides that the hafnium precursor pulse, the optional zirconium precursor pulse, the oxygen reactant pulse and/or the germanium dopant pulse comprise a plurality of micro pulses. A “micro pulse” as used herein is a short period during which one or more hafnium precursor, one or more zirconium precursor, one or more oxygen reactant and/or one or more germanium dopant may be introduced into the reaction chamber. Hence, the method as disclosed herein provides high flexibility in pulse sequence and length, thereby providing a cost-effective and more efficient method than what is disclosed in the state of the art.

In some embodiments, the hafnium precursor pulse and/or the zirconium precursor pulse lasts from at least 0.01 s to at most 120 s, or from at least 0.01 s to at most 0.1 s, or from at least 0.01 s to at most 0.02 s, or from at least 0.02 s to at most 0.05 s, or from at least 0.05 s to at most 0.1 s, or from at least 0.1 s to at most 20 s, or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s. In some embodiments, the oxygen reactant pulse lasts from at least 0.1 s to at most 20 s or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s, or from at least 20.0 s to at most 120.0 s, or from at least 20.0 s to at most 50.0 s, or from at least 50.0 s to at most 80.0 s, or from at least 80.0 s to at most 120.0 s. In some embodiments, the germanium dopant pulse lasts from at least 0.1 s to at most 20 s or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s, or from at least 20.0 s to at most 120.0 s, or from at least 20.0 s to at most 50.0 s, or from at least 50.0 s to at most 80.0 s, or from at least 80.0 s to at most 120.0 s.

It shall be understood that any two steps and/or pulses and/or micro pulses can be separated by a purge. Thus, in some embodiments, a hafnium precursor pulse and/or a zirconium precursor pulse, and an oxygen reactant pulse may be separated by a purge. In some embodiments, a germanium dopant pulse is preceded by a purge. In some embodiments, subsequent cycles are separated by a purge. In particular embodiments, the reaction chamber is purged before and/or after each hafnium precursor pulse, optional zirconium precursor pulse, oxygen reactant pulse and/or germanium dopant pulse. An advantage of purging the reaction chamber before and/or after each precursor pulse, reactant pulse, and/or dopant pulse is that any residual precursor, reactant, dopant and/or reaction byproducts is removed, thereby avoiding cross-contamination between pulses and resulting in films or layers with high purity and less defects.

In some embodiments, the plurality of deposition cycles can comprise a plurality of master cycles. A master cycle can comprise a germanium dopant pulse and one or more sub-cycles. A sub-cycle can comprise a hafnium precursor pulse and/or a zirconium precursor pulse and an oxygen reactant pulse. Thus, in some embodiments, the plurality of deposition cycles can be represented by formula i)

[(hafnium precursor+oxygen reactant)×sub-cycle+germanium dopant]×master cycle i)

Additionally, or alternatively, and in some embodiments, the plurality of deposition cycles can be represented by formula ii)

[(hafnium precursor+zirconium precursor+oxygen reactant)×sub-cycle+germanium dopant]×master cycle ii)

Additionally, or alternatively, and in some embodiments, the plurality of deposition cycles can be represented by formula iii)

[(oxygen reactant+hafnium precursor)×sub-cycle+germanium dopant]×master cycle iii)

Additionally, or alternatively, and in some embodiments, the plurality of deposition cycles can be represented by formula iv)

[(oxygen reactant+hafnium precursor+zirconium precursor)×sub-cycle+germanium dopant]×master cycle iv)

Additionally, or alternatively, and in some embodiments, the plurality of deposition cycles can be represented by formula v)

[(oxygen reactant+zirconium precursor+hafnium precursor)×sub-cycle+germanium dopant]×master cycle v)

In which “hafnium precursor” denotes a hafnium precursor pulse, “zirconium precursor” denotes a zirconium precursor pulse, “oxygen reactant” denotes an oxygen reactant pulse, “x sub-cycle” denotes the number of sub-cycles per master cycle, “germanium dopant” denotes a germanium dopant pulse, “x master cycle” denotes the number of master cycles, and “+” denotes that one pulse occurs after the other.

In some embodiments, the method comprises from at least 2 sub-cycles to at most 5 sub-cycles, or from at least 5 sub-cycles to at most 10 sub-cycles, or from at least 10 sub-cycles to at most 20 sub-cycles, or from at least 20 sub-cycles to at most 50 sub-cycles, or from at least 50 sub-cycles to at most 100 sub-cycles, or from at least 100 sub-cycles to at most 200 sub-cycles, or from at least 200 sub-cycles to at most 500 sub-cycles, or from at least 500 sub-cycles to at most 1000 sub-cycles, or from at least 1000 sub-cycles to at most 2000 sub-cycles.

In the present disclosure, germanium dopants can be strategically introduced to create “charge storage sites” or “charge traps” within a charge trapping layer. The charge storage sites control the trapping and release of charge carriers such as electrons or holes, which can represent the data state of a memory cell. It has been found by the present inventors that germanium dopants can be particularly useful to improve the efficiency of charge trapping in the charge retention structure. Without wishing to be bound by theory, it is believed that germanium doping of a HfO₂ film and/or a HZO film, according to the disclosure, can improve the charge retention characteristics of the charge trapping layer by generating deep charge traps (i.e., with a high barrier for release of charge carriers). This can enhance the ability of the charge trapping layer to capture and hold charges during programming and erasing operations of a memory element, leading to reliable and consistent data storage. In some embodiments, the germanium dopant may be introduced into the growing HfO₂ film and/or the HZO film (i.e., during the film deposition). In some embodiments, the germanium dopant may be introduced after formation of the HfO₂ film and/or the HZO film (i.e., after the film is deposited in one or more sub-cycles).

In particular embodiments, the method as disclosed herein provides that the one or more germanium dopant is represented by the following general formula (I) or (II),

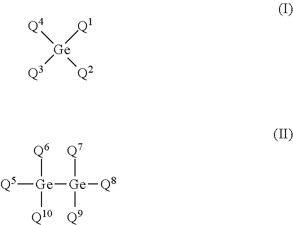

wherein Q¹, Q², Q³, Q⁴, Q⁵, Q⁶, Q⁷, Q⁸, Q⁹, Q¹⁰ are each independently chosen from the group consisting of hydrogen, halogen, alkyl, alkenyl, N(R¹)₂, (R²)₂NR³N(R⁴)₂, alkoxy, heteroalkyl, cycloalkoxy, cycloalkyl, aryl, and (R₆R₇N)(R₈R₉N)C═N—R₁₀; wherein each R¹, R², and R⁴ is independently hydrogen, alkyl, alkenyl, or Si(R⁵)₃; wherein each R³ is alkyl; and wherein each R⁵ is independently hydrogen, or alkyl; and wherein (R₆R₇N)(R₈R₉N)C═N—R₁₀ is 1,3,4,6,7,8-Hexahydro-2H-pyrimido[1,2-a]pyrimidine.

The term “halo” or “halogen” as a group or part of a group is generic for fluoro (F), chloro (Cl), bromo (Br), iodo (I).

The term “alkyl” as a group or part of a group, refers to a hydrocarbyl group of formula CₙH₂ₙ₊₁ wherein n is a number greater than or equal to 1. Alkyl groups may be linear or branched and may be substituted as indicated herein. Generally, alkyl groups of this disclosure comprise from 1 to 20 carbon atoms, preferably from 1 to 10 carbon atoms, preferably from 1 to 8 carbon atoms, preferably from 1 to 6 carbon atoms, more preferably from 1 to 4 carbon atoms. When a subscript is used herein following a carbon atom, the subscript refers to the number of carbon atoms that the named group may contain. For example, the term “C₁₋₂₀alkyl”, as a group or part of a group, refers to a hydrocarbyl group of formula —CₙH₂ₙ₊₁ wherein n is a number ranging from 1 to 20. Thus, for example, “C₁₋₈alkyl” includes all linear or branched alkyl groups with between 1 and 8 carbon atoms, and thus includes methyl, ethyl, n-propyl, i-propyl, butyl and its isomers (e.g. n-butyl, i-butyl and t-butyl); pentyl and its isomers, hexyl and its isomers, etc. A “substituted alkyl” refers to an alkyl group substituted with one or more substituent(s) (for example 1 to 3 substituent(s), for example 1, 2, or 3 substituent(s)) at any available point of attachment.

When the suffix “ene” is used in conjunction with an alkyl group, i.e. “alkylene”, this is intended to mean the alkyl group as defined herein having two single bonds as points of attachment to other groups. As used herein, the term “alkylene” also referred as “alkanediyl”, by itself or as part of another substituent, refers to alkyl groups that are divalent, i.e., with two single bonds for attachment to two other groups. Alkylene groups may be linear or branched and may be substituted as indicated herein. Non-limiting examples of alkylene groups include methylene (—CH₂—), ethylene (—CH₂—CH₂—), methylmethylene (—CH(CH₃)—), 1-methyl-ethylene (—CH(CH₃)—CH₂—), n-propylene (—CH₂—CH₂—CH₂—), 2-methylpropylene (—CH₂—CH(CH₃)—CH₂—), 3-methylpropylene (—CH₂—CH₂—CH(CH₃)—), n-butylene (—CH₂—CH₂—CH₂—CH₂—), 2-methylbutylene (—CH₂—CH(CH₃)—CH₂—CH₂—), 4-methylbutylene (—CH₂—CH₂—CH₂—CH(CH₃)—), pentylene and its chain isomers, hexylene and its chain isomers.

The term “alkenyl” as a group or part of a group, refers to an unsaturated hydrocarbyl group, which may be linear, or branched, comprising one or more carbon-carbon double bonds.

Generally, alkenyl groups of this disclosure comprise from 3 to 20 carbon atoms, preferably from 3 to 10 carbon atoms, preferably from 3 to 8 carbon atoms. When a subscript is used herein following a carbon atom, the subscript refers to the number of carbon atoms that the named group may contain. Examples of C₃₋₂₀alkenyl groups are ethenyl, 2-propenyl, 2-butenyl, 3-butenyl, 2-pentenyl and its isomers, 2-hexenyl and its isomers, 2,4-pentadienyl, and the like.

The term “alkoxy” or “alkyloxy”, as a group or part of a group, refers to a group having the formula —OR^{b} wherein R^{b} is alkyl as defined herein above. Non-limiting examples of suitable alkoxy include methoxy, ethoxy, propoxy, isopropoxy, butoxy, isobutoxy, sec-butoxy, tert-butoxy, pentyloxy and hexyloxy.

The term “cycloalkyl”, as a group or part of a group, refers to a cyclic alkyl group, that is a monovalent, saturated, hydrocarbyl group having 1 or more cyclic structure, and comprising from 3 to 20 carbon atoms, more preferably from 3 to 10 carbon atoms, more preferably from 3 to 8 carbon atoms; more preferably from 3 to 6 carbon atoms. Cycloalkyl includes all saturated hydrocarbon groups containing 1 or more rings, including monocyclic, bicyclic groups or tricyclic. The further rings of multi-ring cycloalkyls may be either fused, bridged and/or joined through one or more spiro atoms. When a subscript is used herein following a carbon atom, the subscript refers to the number of carbon atoms that the named group may contain. For example, the term “C₃₋₂₀cycloalkyl”, a cyclic alkyl group comprising from 3 to 20 carbon atoms. For example, the term “C₃₋₁₀cycloalkyl”, a cyclic alkyl group comprising from 3 to 10 carbon atoms. For example, the term “C₃₋₈cycloalkyl”, a cyclic alkyl group comprising from 3 to 8 carbon atoms. For example, the term “C₃₋₆cycloalkyl”, a cyclic alkyl group comprising from 3 to 6 carbon atoms. Examples of C₃₋₁₂cycloalkyl groups include but are not limited to adamantly, cyclopropyl, cyclobutyl, cyclopentyl, cyclohexyl, cycloheptyl, cyclooctyl, bicycle[2.2.1]heptan-2yl, (1S,4R)-norbornan-2-yl, (1R,4R)-norbornan-2-yl, (1S,4S)-norbornan-2-yl, (1R,4S)-norbornan-2-yl.

When the suffix “ene” is used in conjunction with a cycloalkyl group, i.e. cycloalkylene, this is intended to mean the cycloalkyl group as defined herein having two single bonds as points of attachment to other groups. Non-limiting examples of “cycloalkylene” include 1,2-cyclopropylene, 1,1-cyclopropylene, 1,1-cyclobutylene, 1,2-cyclobutylene, 1,3-cyclopentylene, 1,1-cyclopentylene, and 1,4-cyclohexylene.

Where an alkylene or cycloalkylene group is present, connectivity to the molecular structure of which it forms part may be through a common carbon atom or different carbon atom. To illustrate this applying the asterisk nomenclature of this disclosure, a C₃alkylene group may be for example *—CH₂CH₂CH₂—*, *—CH(—CH₂CH₃)—* or *—CH₂CH(—CH₃)—*. Likewise, a C₃cycloalkylene group may be

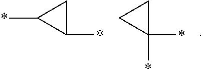

The term “aryl”, as a group or part of a group, refers to a polyunsaturated, aromatic hydrocarbyl group having a single ring (i.e. phenyl) or multiple aromatic rings fused together (e.g. naphthyl), or linked covalently, typically containing 6 to 20 atoms; preferably 6 to 10, wherein at least one ring is aromatic. The aromatic ring may optionally include one to two additional rings (either cycloalkyl, heterocyclyl or heteroaryl) fused thereto. Examples of suitable aryl include C₆₋₂₀aryl, preferably C₆₋₁₀aryl, more preferably C₆₋₈aryl. Non-limiting examples of aryl comprise phenyl, biphenylyl, biphenylenyl, or 1- or 2-naphthanelyl; 1-, 2-, 3-, 4-, 5- or 6-tetralinyl (also known as “1,2,3,4-tetrahydronaphtalene); 1-, 2-, 3-, 4-, 5-, 6-, 7- or 8-azulenyl, 4-, 5-, 6 or 7-indenyl; 4- or 5-indanyl; 5-, 6-, 7- or 8-tetrahydronaphthyl; 1,2,3,4-tetrahydronaphthyl; and 1,4-dihydronaphthyl; 1-, 2-, 3-, 4- or 5-pyrenyl. A “substituted aryl” refers to an aryl group having one or more substituent(s)(for example 1, 2 or 3 substituent(s), or 1 to 2 substituent(s)), at any available point of attachment.

The term “cycloalkoxy”, as a group or part of a group, refers to a group having the formula —OR^{c} wherein R^{c} is cycloalkyl as defined herein above.

The term “heteroalkyl” as a group or part of a group, refers to an acyclic alkyl wherein one or more carbon atoms are replaced by at least one heteroatom selected from the group comprising O, Si, S, B, and P, with the proviso that the chain may not contain two adjacent heteroatoms. This means that one or more —CH₃ of the acyclic alkyl can be replaced by —OH for example and/or that one or more —CR₂— of the acyclic alkyl can be replaced by O, Si, S, B, and P.

In some embodiments, the present disclosure provides that Q¹, Q², Q³, Q⁴, Q⁵, Q⁶, Q⁷, Q⁸, Q⁹, Q¹⁰ are each independently chosen from the group consisting of hydrogen, halogen, C₁₋₈alkyl, C₂₋₈alkenyl, N(R¹)₂, (R²)₂NR³N(R⁴)₂, C₁₋₄alkoxy, heteroC₁₋₄alkyl, C₃₋₈cycloalkoxy, C₃₋₈cycloalkyl, C₆₋₁₀aryl, (R₆R₇N)(R₈R₉N)C═N—R₁₀; wherein each R¹, R², and R⁴ is independently hydrogen, C₁₋₈alkyl, C₂₋₈alkenyl, or Si(R⁵)₃; wherein each R³ is C₁₋₈alkyl; wherein each R⁵ is independently hydrogen, or C₁₋₈alkyl; and wherein (R₆R₇N)(R₈R₉N)C═N—R₁₀ is 1,3,4,6,7,8-Hexahydro-2H-pyrimido[1,2-a]pyrimidine.

In some embodiments, the present disclosure provides that Q¹, Q², Q³, Q⁴, Q⁵, Q⁶, Q⁷, Q⁸, Q⁹, Q¹⁰ are each independently chosen from the group consisting of hydrogen, halogen, C₁₋₄alkyl, C₂₋₄alkenyl, N(R¹)₂, (R²)₂NR³N(R⁴)₂, C₁₋₄alkoxy, heteroC₁₋₄alkyl, C₃₋₈cycloalkoxy, C₃₋₈cycloalkyl, C₆₋₁₀aryl, (R₆R₇N)(R₈R₉N)C═N—R₁₀; wherein each R¹, R², and R⁴ is independently hydrogen, C₁₋₄ alkyl, C₂₋₄alkenyl, or Si(R⁵)₃; wherein each R³ is C₁₋₄alkyl; wherein each R⁵ is independently hydrogen, or C₁₋₄alkyl; and wherein (R₆R₇N)(R₈R₉N)C═N—R₁₀ is 1,3,4,6,7,8-Hexahydro-2H-pyrimido[1,2-a]pyrimidine.

According to a particular embodiment, the method as disclosed herein provides that for the one or more germanium dopant represented by the general formula (I) or (II), the alkyl is a C₁₋₈alkyl, and more in particular a C₁₋₄alkyl. More in particular the alkyl is a C₁, C₂, C₃, C₄, C₅, C₆, C₇, and/or C₈ alkyl.

According to a particular embodiment, the method as disclosed herein provides that for the one or more germanium dopant represented by the general formula (I) or (II), the alkenyl is a C₂₋₈alkenyl, and more in particular a C₂₋₄alkenyl. More in particular the alkenyl is a C₂, C₃, C₄, C₅, C₆, C₇, and/or C₈ alkenyl.

According to a particular embodiment, the method as disclosed herein provides that for the one or more germanium dopant represented by the general formula (I) or (II), the alkoxy is a C₁₋₈alkoxy, and more in particular a C₁₋₄alkoxy. More in particular the alkoxy is a C₁, C₂, C₃, C₄, C₅, C₆, C₇, and/or C₈ alkoxy.

According to a particular embodiment, the method as disclosed herein provides that for the one or more germanium dopant represented by the general formula (I) or (II), the heteroalkyl is a heteroC₁₋₈alkyl, and more in particular a heteroC₁₋₄alkyl. More in particular the heteroalkyl is a C₁, C₂, C₃, C₄, C₅, C₆, C₇, and/or C₈ heteroalkyl.

According to a particular embodiment, the method as disclosed herein provides that for the one or more germanium dopant represented by the general formula (I) or (II), the cycloalkoxy is a C₃₋₈cycloalkoxy. More in particular the cycloalkoxy is a C₃, C₄, C₅, C₆, C₇, and/or C₈ cycloalkoxy.

According to a particular embodiment, the method as disclosed herein provides that for the one or more germanium dopant represented by the general formula (I) or (II), the cycloalkyl is a C₃₋₈cycloalkyl. More in particular the cycloalkyl is a C₃, C₄, C₅, C₆, C₇, and/or C₈ cycloalkyl.

According to a particular embodiment, the method as disclosed herein provides that for the one or more germanium dopant represented by the general formula (I) or (II), the aryl is a C₆₋₁₀aryl. More in particular the aryl is a C₆, C₇, C₈, C₉, and/or C₁₀ aryl.

In particular embodiments, the method as disclosed herein provides that the one or more germanium dopant is chosen from the group consisting of Ge₂H₆, GeH₄, GeF₄, GeHF₃, GeH₂F₂, GeH₃F₁, GeCl₄, GeHCl₃, GeH₂Cl₂, GeH₃Cl₁, GeBr₄, GeHBr₃, GeH₂Br₂, GeH₃Br₁, GeI₄, GeHI₃, GeH₂I₂, GeH₃I₁, GeF₂(C₄HsO₂), GeCl₂(C₄H₈O₂), GeBr₂(C₄H₈O₂), GeI₂(C₄H₈O₂), GeH₂Me₂, GeH₂Et₂, GeH₂(i-Pr)₂, GeH(n-Bu)₃, Ge(NMe₂)₄, Ge(NMeEt)₄, Ge(NEt₂)₄, Ge[N(SiMe₃)₂]₄, Ge(NMe₂)₂[N(SiMe₃)₂]₂, Ge(NMe₂)₂[NHt-Bu(CH₂)₂NHt-Bu], Ge[NHt-Bu(CH₂)₂NHt-Bu]₂, Ge(NMe₂)₂[NHi-Pr(CH₂)₂NHi-Pr], Ge[NHi-Pr(CH₂)₂NHi-Pr]₂, Ge(OMe)₄, Ge(OEt)₄, Ge(Oi-Pr)₄, Ge(Ot-Bu)₄, or Ge(On-Bu)₄, GeN(CH₃)₂[(Ni—Pr)₂C═N—(CH₃)₂], and GeN(CH₃)₂[1,3,4,6,7,8-Hexahydro-2H-pyrimido[1,2-a]pyrimidine]. Extensive experimentation has shown that the herein disclosed germanium dopants provide a good balance between volatility and reactivity, resulting in efficient transfer of the germanium dopant to the substrate.

In a particular embodiment, the method as disclosed herein provides that the one or more germanium dopant is Ge(NMe₂)₄.

In some embodiments, the implanting dosage or molar atomic percentage of the germanium dopant in the one or more deposited HfO₂ film and/or the one or more deposited HZO film ranges from 0.10 at. % to 15.0 at. %, or 0.50 at. % to 15.0 at. %, or 1.0 at. % to 15.0 at. %, or 5.0 at. % to 15.0 at. %, or 5.0 at. % to 10.0 at. %. Preferably, the implanting dosage or molar atomic percentage of the germanium dopant in the one or more deposited HfO₂ film and/or the one or more deposited HZO film is less than 10.0 at. %, such as less than 9.0 at. %, or less than 8.0 at. %, or less than 7.0 at. %, or less than 6.0 at. %, or less than 5.0 at. %, or less than 4.0 at. %, or less than 3.0 at. %, or less than 2.0 at. %, or less than 1.0 at. %, or less than 0.50 at. %. Advantageously, the present method allows to introduce germanium dopants at specific positions and with defined concentration in the charge trapping layer. Specific positions may include the bulk material of the charge trapping layer and/or the surface of the charge trapping layer. In some embodiments, only a small amount of germanium dopants is needed (at specific positions) to provide strong charge retention of the charge trapping layer, therefore providing a cost-effective and efficient doping method.

In contrast to existing charge trap layers comprising SiN, the present disclosure relies on the formation of a doped metal oxide film or layer. It was found by the inventors that hafnium oxide layers and/or hafnium zirconium oxide layers can provide particularly improved charge trap efficiency over SiN. Moreover, by doping the formed hafnium oxide layers and/or hafnium zirconium oxide layers with a germanium dopant, the charge loss rate can be reduced.

In the present disclosure, one or more metal precursor (e.g. hafnium and/or zirconium) may adhere and bind to a substrate. It was found that particularly hafnium metal and/or zirconium metal provide strong chemisorption to the deposition surface, resulting in a thin film or layer with high integrity and functionality.

In a particular embodiment, the method as disclosed herein provides that the one or more hafnium precursor is represented by the following general formula (III),

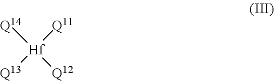

wherein Q¹¹, Q¹², Q¹³, Q¹⁴ are each independently chosen from the group consisting of halogen, alkyl, alkenyl, N(R¹)₂, alkoxy, heteroalkyl, cycloalkyl, aryl, and cyclopentadienyl; wherein each R¹ is independently hydrogen, alkyl, or alkenyl.

The term “cyclopentadienyl” as a group or part of a group, refers to a group having the formula (V)

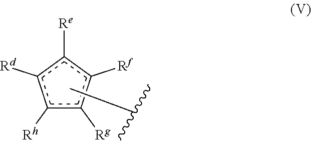

wherein R^{d}, R^{e}, R^{f}, R^{g}, R^{h} are each independently selected from the group consisting of hydrogen, alkyl, alkenyl, alkoxy, or heteroalkyl as defined herein above. As disclosed herein, cyclopentadienyl is a 5-member carbon ring bound to metal such as hafnium and/or zirconium through covalent η5-bonds. Thus, for example, “cyclopentadienyl” refers to both hydrogenated cyclopenta-2,4-dien-1-yl (Cp) and substituted cyclopenta-2,4-dien-1-yl, such as, methyl-cyclopenta-2,4-dien-1-yl (MeCp), ethyl-cyclopenta-2,4-dien-1-yl (EtCp), and n-propyl-cyclopenta-2,4-dien-1-yl (n-PrCp).

In some embodiments, the present disclosure provides that Q¹¹, Q¹², Q¹³, Q¹⁴ are each independently chosen from the group consisting of halogen, C₁₋₈alkyl, C₂₋₈alkenyl, N(R¹)₂, C₁₋₈alkoxy, heteroC₁₋₈alkyl, C₃₋₈cycloalkyl, C₆₋₁₀aryl, and cyclopentadienyl; wherein each R¹ is independently hydrogen, C₁₋₈alkyl, or C₂₋₈alkenyl.

In some embodiments, the present disclosure provides that Q¹¹, Q¹², Q¹³, Q¹⁴ are each independently chosen from the group consisting of halogen, C₁₋₄alkyl, C₂₋₄alkenyl, N(R¹)₂, C₁₋₄alkoxy, heteroC₁₋₄alkyl, C₃₋₈cycloalkyl, C₆₋₁₀aryl, and cyclopentadienyl; wherein each R¹ is independently hydrogen, C₁₋₄alkyl, or C₂₋₄alkenyl.

According to a particular embodiment, the method as disclosed herein provides that for the one or more germanium dopant represented by the general formula (III), the alkyl is a C₁₋₈alkyl, and more in particular a C₁₋₄alkyl. More in particular the alkyl is a C₁, C₂, C₃, C₄, C₅, C₆, C₇, and/or C₈ alkyl.

According to a particular embodiment, the method as disclosed herein provides that for the one or more germanium dopant represented by the general formula (III), the alkenyl is a C₂₋₈alkenyl, and more in particular a C₂₋₄alkenyl. More in particular the alkenyl is a C₂, C₃, C₄, C₅, C₆, C₇, and/or C₈ alkenyl.

According to a particular embodiment, the method as disclosed herein provides that for the one or more germanium dopant represented by the general formula (III), the alkoxy is a C₁₋₈alkoxy, and more in particular a C₁₋₄alkoxy. More in particular the alkoxy is a C₁, C₂, C₃, C₄, C₅, C₆, C₇, and/or C₈ alkoxy.

According to a particular embodiment, the method as disclosed herein provides that for the one or more germanium dopant represented by the general formula (III), the heteroalkyl is a heteroC₁₋₈alkyl, and more in particular a heteroC₁₋₄alkyl. More in particular the heteroalkyl is a C₁, C₂, C₃, C₄, C₅, C₆, C₇, and/or C₈ heteroalkyl.

According to a particular embodiment, the method as disclosed herein provides that for the one or more germanium dopant represented by the general formula (III), the cycloalkoxy is a C₃₋₈cycloalkoxy. More in particular the cycloalkoxy is a C₃, C₄, C₅, C₆, C₇, and/or C₈ cycloalkoxy.

According to a particular embodiment, the method as disclosed herein provides that for the one or more germanium dopant represented by the general formula (III), the cycloalkyl is a C₃₋₈cycloalkyl. More in particular the cycloalkyl is a C₃, C₄, C₅, C₆, C₇, and/or C₈ cycloalkyl.

According to a particular embodiment, the method as disclosed herein provides that for the one or more germanium dopant represented by the general formula (III), the aryl is a C₆₋₁₀aryl. More in particular the aryl is a C₆, C₇, C₈, C₉, and/or C₁₀ aryl.

In particular embodiments, the method as disclosed herein provides that the one or more hafnium precursor is chosen from the group consisting of HfCl₄, HfBr₄, HfI₄, HfMe₄, HfEt₄, Hf(nPr)₄, Hf(iPr)₄, Hf(nBu)₄, Hf(tBu)₄, Hf(NMe₂)₄, Hf(NEt₂)₄, Hf[MeEtN]₄, HfCp[(NMe₂)₃], Hf(OMe)₄, Hf(OEt)₄, Hf(OnPr)₄, Hf(OiPr)₄, Hf(OnBu)₄, Hf(OtBu)₄, Hf[(CpMe)₂][OMe][Me], Hf[(CpMe)₂][(Me)₂], Tetrakis(1-methoxy-2-methyl-2-propoxy)hafnium (Hf(mmp)₄).

In a particular embodiment, the method as disclosed herein provides that the one or more zirconium precursor is represented by the following general formula (IV),

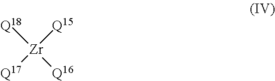

wherein Q¹⁵, Q¹⁶, Q¹⁷, Q¹⁸ are each independently chosen from the group consisting of halogen, alkyl, alkenyl, N(R¹)₂, alkoxy, heteroalkyl, cycloalkyl, aryl, and cyclopentadienyl; wherein each R¹ is independently hydrogen, alkyl, or alkenyl.

In some embodiments, the present disclosure provides that Q¹⁵, Q¹⁶, Q¹⁷, Q¹⁸ are each independently chosen from the group consisting of halogen, C₁₋₈alkyl, C₂₋₈alkenyl, N(R¹)₂, C₁₋₈alkoxy, heteroC₁₋₈alkyl, C₃₋₈cycloalkyl, C₆₋₁₀aryl, and cyclopentadienyl; wherein each R¹ is independently hydrogen, C₁₋₈alkyl, or C₂₋₈alkenyl.

In some embodiments, the present disclosure provides that Q¹⁵, Q¹⁶, Q¹⁷, Q¹⁸ are each independently chosen from the group consisting of halogen, C₁₋₄alkyl, C₂₋₄alkenyl, N(R¹)₂, C₁₋₄alkoxy, heteroC₁₋₄alkyl, C₃₋₈cycloalkyl, C₆₋₁₀aryl, and cyclopentadienyl; wherein each R¹ is independently hydrogen, C₁₋₄alkyl, or C₂₋₄alkenyl.

According to a particular embodiment, the method as disclosed herein provides that for the one or more germanium dopant represented by the general formula (V), the alkyl is a C₁₋₈alkyl, and more in particular a C₁₋₄alkyl. More in particular the alkyl is a C₁, C₂, C₃, C₄, C₅, C₆, C₇, and/or C₈ alkyl.

According to a particular embodiment, the method as disclosed herein provides that for the one or more germanium dopant represented by the general formula (V), the alkenyl is a C₂₋₈alkenyl, and more in particular a C₂₋₄alkenyl. More in particular the alkenyl is a C₂, C₃, C₄, C₅, C₆, C₇, and/or C₈ alkenyl.

According to a particular embodiment, the method as disclosed herein provides that for the one or more germanium dopant represented by the general formula (V), the alkoxy is a C₁₋₈alkoxy, and more in particular a C₁₋₄alkoxy. More in particular the alkoxy is a C₁, C₂, C₃, C₄, C₅, C₆, C₇, and/or C₈ alkoxy.

According to a particular embodiment, the method as disclosed herein provides that for the one or more germanium dopant represented by the general formula (V), the heteroalkyl is a heteroC₁₋₈alkyl, and more in particular a heteroC₁₋₄alkyl. More in particular the heteroalkyl is a C₁, C₂, C₃, C₄, C₅, C₆, C₇, and/or C₈ heteroalkyl.

According to a particular embodiment, the method as disclosed herein provides that for the one or more germanium dopant represented by the general formula (V), the cycloalkoxy is a C₃₋₈cycloalkoxy. More in particular the cycloalkoxy is a C₃, C₄, C₅, C₆, C₇, and/or C₈ cycloalkoxy.

According to a particular embodiment, the method as disclosed herein provides that for the one or more germanium dopant represented by the general formula (V), the cycloalkyl is a C₃₋₈cycloalkyl. More in particular the cycloalkyl is a C₃, C₄, C₅, C₆, C₇, and/or C₈ cycloalkyl.

According to a particular embodiment, the method as disclosed herein provides that for the one or more germanium dopant represented by the general formula (V), the aryl is a C₆₋₁₀aryl. More in particular the aryl is a C₆, C₇, C₈, C₉, and/or C₁₀ aryl.

In particular embodiments, the method as disclosed herein provides that the one or more zirconium precursor is chosen from the group consisting of ZrCl₄, ZrBr₄, ZrI₄, ZrMe₄, ZrEt₄, Zr(nPr)₄, Zr(iPr)₄, Zr(nBu)₄, Zr(tBu)₄, Zr(NMe₂)₄, Zr(NEt₂)₄, Zr[MeEtN]₄, ZrCp[(NMe₂)₃], Zr(OMe)₄, Zr(OEt)₄, Zr(OnPr)₄, Zr(OiPr)₄, Zr(OnBu)₄, Zr(OtBu)₄, Zr[(CpMe)₂][OMe][Me], Zr[(CpMe)₂][(Me)₂], Tetrakis(1-methoxy-2-methyl-2-propoxy)zirconium (Zr(mmp)₄). Advantageously, the hafnium precursor and/or zirconium precursor disclosed herein are specifically selected to have a low volatility and can thereby be easy to vaporize.

In the present disclosure, one or more oxygen reactant may react with the chemisorbed hafnium and/or zirconium. In particular embodiments, the one or more oxygen reactant is chosen from the group consisting of H₂O, H₂O₂, O₃, O₂, O-containing plasma, N₂O, NO, N₂O₅, and oxygen radicals.

The method as disclosed herein may be performed at different temperatures and/or pressures. In particular embodiments, the method as disclosed herein provides that the substrate may be heated to a temperature of about 80° C. to about 400° C., or about 100° C. to about 400° C., or about 125° C. to about 400° C., preferably about 150° C. to about 400° C., or about 175° C. to about 400° C., preferably about 200° C. to about 400° C., or about 250° C. to about 400° C., or about 300° C. to about 400° C. The listed temperatures can decrease the time needed for material deposition, although lower or higher temperatures can be considered still.

In particular embodiments, the method as disclosed herein provides that the pressure in the reaction chamber is between about 0.1 Torr and about 100.0 Torr, or between about 0.5 Torr and about 100.0 Torr, or between about 1.0 Torr and about 100.0 Torr, or between about 2.0 Torr and about 100.0 Torr, or between about 5.0 Torr and about 100.0 Torr, or between about 5.0 Torr and about 80.0 Torr, or preferably between about 5.0 Torr and about 50.0 Torr, or between about 10.0 Torr and about 50.0 Torr. The listed pressures can decrease the time needed for material deposition, although lower or higher pressures can be considered still.

The germanium-doped HfO₂ film and/or the germanium-doped HZO film may be formed in any suitable reactor. Thus, in some embodiments, the germanium-doped HfO₂ film and/or the germanium-doped HZO film is deposited in a cross-flow reactor. In some embodiments, the germanium-doped HfO₂ film and/or the germanium-doped HZO film is deposited in a showerhead reactor. In some embodiments, the germanium-doped HfO₂ film and/or the germanium-doped HZO film is deposited in a hot-wall reactor. In some embodiments, the germanium-doped HfO₂ film and/or the germanium-doped HZO film is deposited in a cold-wall reactor. Doing so can advantageously enhance uniformity and/or repeatability of the germanium-doped HfO₂ film and/or the germanium-doped HZO film deposition processes.

In some embodiments, the substrate is subjected to an annealing step in an ambient comprising hydrogen and nitrogen after the cyclical deposition process. Suitably, the annealing step can be carried out at a temperature from at least 300° C. to at most 600° C. Alternatively, the annealing step can be carried out at a temperature from at least 300° C. to at most 1000° C.

In some embodiments, the hafnium precursor, the zirconium precursor and/or the oxygen reactant is provided to the reaction chamber by means of a carrier gas. Exemplary carrier gasses include nitrogen (N₂) and a noble gas such as He, Ne, Ar, Xe, or Kr.

Another aspect of the present disclosure relates to a system comprising:
a reaction chamber constructed and arranged to hold a substrate;
a hafnium precursor vessel constructed and arranged to contain and evaporate one or more hafnium precursor;
a zirconium precursor vessel constructed and arranged to contain and evaporate one or more zirconium precursor;
an oxygen reactant vessel constructed and arranged to contain and evaporate one or more oxygen reactant;
a germanium dopant vessel constructed and arranged to contain and evaporate one or more germanium dopant;
a controller, operatively connected to the hafnium precursor vessel, the zirconium precursor vessel, the oxygen reactant vessel, and the germanium dopant vessel;
wherein the controller is configured to control the introduction of the one or more hafnium precursor, the one or more zirconium precursor, the one or more oxygen reactant, and the one or more germanium dopant into the reaction chamber during one or more cycles, wherein, as a result of the cycles, a charge trapping layer comprising one or more germanium-doped HfO₂ film and/or one or more germanium-doped HZO film is formed on the substrate.

In a particular embodiment, the system as disclosed herein provides that as a result of the cycles, a charge trapping layer comprising one or more germanium-doped HfO₂ film and one or more germanium-doped HZO film is formed on the substrate.

In a particular embodiment, the system as disclosed herein provides that said one or more cycles are a plurality of cycles.

It has been found that a controller configured to precisely control the introduction of precursor gas, reactive gas, and dopant gas, is particularly advantageous to perform well-controlled chemical reactions that can result in more uniform and reproducible thin films or layers. Moreover, the controller can adjust the flow rate and timing to optimize the reaction kinetics, resulting in desired film properties such as a reduction in charge leakage of the formed charge trapping layer, a uniform layer thickness, and controlled composition. In particular, the system may be configured to form charge trapping layers with decreased variations in layer thickness, and defects, resulting in improved memory devices.

In particular embodiments, the system as disclosed herein is configured to form a charge trapping layer of a memory element by means of a method as disclosed herein.

In some embodiments, the hafnium precursor, zirconium precursor, oxygen reactant, and/or germanium dopant is provided to the reaction chamber from a temperature-controlled vessel. In some embodiments, the temperature-controlled vessel is configured for cooling the precursors, reactants and/or dopants. In some embodiments, the temperature-controlled vessel is configured for heating the precursors, reactants and/or dopants. In some embodiments, the temperature controlled vessel is maintained at a temperature of at least −50° C. to at most 20° C., or at a temperature of at least 20° C. to at most 250° C., or at a temperature of at least 100° C. to at most 200° C.

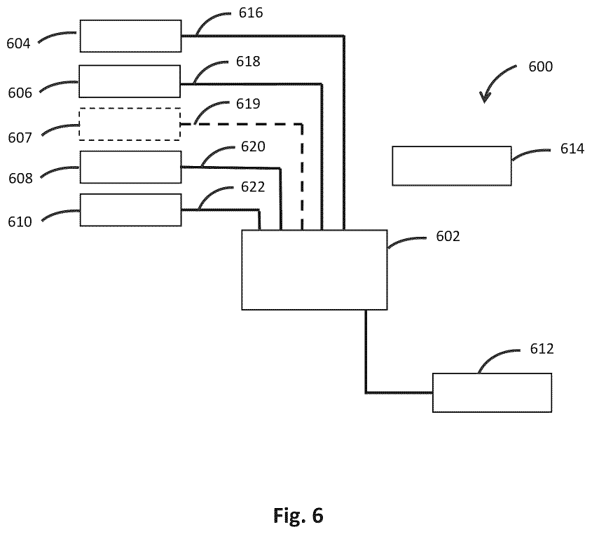

FIG. 6. Schematically illustrates a system (600) in accordance with yet additional exemplary embodiments of the disclosure. The system (600) can be used to perform a method as described herein and/or form a structure or device portion as described herein.

In the illustrated example, the system (600) includes one or more reaction chambers (602), a hafnium precursor gas source (604), an oxygen reactant gas source (606), a germanium dopant source (608), a purge gas source (610), an exhaust (612), and a controller (614). The reaction chamber (602) can include any suitable reaction chamber, such as an ALD or CVD reaction chamber. Optionally, the system (600) comprises further gas sources such as a zirconium precursor containing gas source (607).

The hafnium precursor gas source (604) can include a vessel and one or more hafnium precursors as described herein-alone or mixed with one or more carrier (e.g., inert) gases. The oxygen reactant gas source (606) can include a vessel and one or more nitrogen reactants as described herein-alone or mixed with one or more carrier gases. The germanium dopant gas source (608) can include a vessel and one or more germanium dopant as described herein-alone or mixed with one or more carrier gases. The purge gas source (610) can include one or more inert gases such as N₂ or a noble gas, as described herein. The system (600) can include any suitable number of gas sources. The gas sources (604)-(610) can be coupled to reaction chamber (602) via lines (616)-(622), which can each include flow controllers, valves, heaters, and the like. The exhaust (612) can include one or more vacuum pumps.

The controller (614) includes electronic circuitry and software to selectively operate valves, manifolds, heaters, pumps and other components included in the system (600). Such circuitry and components operate to introduce precursors, reactants, and purge gases from the respective sources (604)-(610). The controller (614) can control timing of gas pulse sequences, temperature of the substrate and/or reaction chamber, pressure within the reaction chamber, and various other operations to provide proper operation of the system (600). The controller (614) can include control software to electrically or pneumatically control valves to control flow of precursors, reactants (i.e. nitrogen reactants and/or oxygen reactants) and purge gases into and out of the reaction chamber (602). The controller (614) can include modules such as a software or hardware component, e.g., a FPGA or ASIC, which performs certain tasks. A module can advantageously be configured to reside on the addressable storage medium of the control system and be configured to execute one or more processes.

Other configurations of the system (600) are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber (602).

Further, as a schematic representation of a system, many components have been omitted for simplicity of illustration, and such components may include, for example, various valves, manifolds, purifiers, heaters, containers, vents, and/or bypasses.

During operation of the reactor system (600), substrates, such as semiconductor wafers (not illustrated), are transferred from, e.g., a substrate handling system to reaction chamber (602). Once substrate(s) are transferred to the reaction chamber (602), one or more gases from the gas sources (604)-(610), such as precursors, reactants, carrier gases, and/or purge gases, are introduced into reaction chamber (602).

Another aspect of the present disclosure relates to a memory element comprising:
a gate electrode;
a blocking dielectric, the blocking dielectric being adjacent to the gate electrode;
a tunnel dielectric;
a charge trapping layer, the charge trapping layer being positioned between the blocking dielectric and the tunnel dielectric;
an n-type layer, the n-type layer being adjacent to the tunnel dielectric; and
a p-type layer, the p-type layer being adjacent to the n-type layer;
wherein said charge trapping layer is obtained by means of a method as described herein.

Another aspect of the present disclosure relates to a memory element comprising:
a gate electrode;
a blocking dielectric, the blocking dielectric being adjacent to the gate electrode;
a tunnel dielectric;
a charge trapping layer, the charge trapping layer being positioned between the blocking dielectric and the tunnel dielectric;
an n-type layer, the n-type layer being adjacent to the tunnel dielectric; and
a p-type layer, the p-type layer being adjacent to the n-type layer;
wherein said charge trapping layer comprises one or more germanium-doped HZO film.

Advantageously, the herein disclosed memory element can be regarded as a general-purpose technology in the sense that it can be readily adapted for a variety of electronic devices and systems, including but not limited to computers, consumer electronics, communication devices, automotive systems, and industrial control systems. Moreover, the one or more germanium-doped HZO film may be characterized by deep charge traps, resulting in improved charge retention of the charge trapping layer, and allowing the memory element to write, erase, and read data more accurately. In some embodiments, the memory element may be used in solid state drives or memory cards.

In particular embodiments, the memory element as disclosed herein provides that the charge trapping layer further comprises one or more germanium-doped hafnium oxide film and/or one or more hafnium oxide film.

In particular embodiments, the memory element as disclosed herein provides that the germanium-doped HZO layer comprises a Hf/Zr molar atomic ratio of 0.1 to 0.9, or 0.2 to 0.8, or 0.3 to 0.7, or 0.4 to 0.7, or 0.5 to 0.7, or 0.3 to 0.6, and preferably a Hf/Zr molar atomic ratio of about 0.5. This has the advantage of regulating the capacitance of the charge trapping layer without increasing or substantially increasing the charge leakage or charge loss of the charge trapping layer. Outside this range, the charge trapping stability may be affected and/or thicker charge trapping layers may be required.

In particular embodiments, the memory element as disclosed herein provides that said germanium-doped HZO layer comprises a molar atomic percentage of 0.10 at. % to 15.0 at. %, or 0.50 at. % to 15.0 at. %, or 1.0 at. % to 15.0 at. %, or 5.0 at. % to 15.0 at. %, or 5.0 at. % to 10.0 at. %.

Preferably, the germanium dopant in the germanium-doped HZO layer comprises a molar atomic percentage of less than 10.0 at. %, such as less than 9.0 at. %, or less than 8.0 at. %, or less than 7.0 at. %, or less than 6.0 at. %, or less than 5.0 at. %, or less than 4.0 at. %, or less than 3.0 at. %, or less than 2.0 at. %, or less than 1.0 at. %, or less than 0.5 at. %.

In preferred embodiments, the memory element as disclosed herein provides that the charge trapping layer is obtained by means of the method as disclosed herein.

Another aspect of the present disclosure relates to a gate stacked 3D NAND memory comprising a vertical channel and a plurality of floating gate stacks, the floating gate stacks each comprising a tunnel dielectric adjacent to the vertical channel, a charge trapping layer adjacent to the tunnel dielectric, a blocking dielectric adjacent to the charge trapping layer, and a gate electrode adjacent to the blocking dielectric; wherein said charge trapping layer comprises one or more germanium-doped HZO film.

In general, 3D NAND (NOT-AND) memory refers to a type of non-volatile memory technology that enhances data storage capacity and performance by vertically stacking memory cells in multiple layers (e.g. floating gate stacks). Unlike traditional 2D NAND memory devices, the gate stacked 3D NAND memory disclosed herein is suitable for applications requiring large data storage in compact form such as in solid-state drives and memory cards. An advantage of the gate stacked 3D NAND memory comprising the charge trapping layer, which comprises one or more germanium-doped HZO film, is improved performance due to increased charge retention of the charge traps.

In particular embodiments, the herein disclosed gate stacked 3D NAND memory provides that the charge trapping layer further comprises one or more germanium-doped hafnium oxide film and/or one or more hafnium oxide film.

In particular embodiments, the herein disclosed gate stacked 3D NAND memory provides that the germanium-doped HZO layer comprises a Hf/Zr molar atomic ratio of 0.3 to 0.7, and preferably a Hf/Zr molar atomic ratio of about 0.5. This has the advantage of regulating the capacitance of the charge trapping layer without increasing or substantially increasing the charge leakage or charge loss of the charge trapping layer. Outside this range, the charge trapping stability may be affected and/or thicker charge trapping layers may be required.

In particular embodiments, the herein disclosed gate stacked 3D NAND memory provides that the germanium-doped HZO layer comprises a molar atomic percentage of 0.10 at. % to 15.0 at. %, or 0.50 at. % to 15.0 at. %, or 1.0 at. % to 15.0 at. %, or 5.0 at. % to 15.0 at. %, or 5.0 at. % to 10.0 at. %. Preferably, the germanium dopant in the germanium-doped HZO layer comprises a molar atomic percentage of less than 10.0 at. %, such as less than 9.0 at. %, or less than 8.0 at. %, or less than 7.0 at. %, or less than 6.0 at. %, or less than 5.0 at. %, or less than 4.0 at. %, or less than 3.0 at. %, or less than 2.0 at. %, or less than 1.0 at. %, or less than 0.50 at. %.

In preferred embodiments, the herein disclosed gate stacked 3D NAND memory provides that the charge trapping layer is obtained by means of the method as disclosed herein.

In preferred embodiments, the herein disclosed gate stacked 3D NAND memory further comprises a memory element according to the memory element as disclosed herein.

Another aspect of the present disclosure relates to a use of a germanium precursor for increasing the charge trap and decreasing the charge loss rate of charge trap layers in a semiconductor structure.

In particular embodiments, the use as disclosed herein provides that said germanium precursor is represented by the general formula (I) or (II),

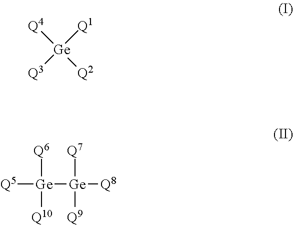

wherein Q¹, Q², Q³, Q⁴, Q⁵, Q⁶, Q⁷, Q⁸, Q⁹, and Q¹⁰ have the meaning as defined herein above.

In some embodiments, the use as disclosed herein provides that the germanium precursor is chosen from the group consisting of Ge₂H₆, GeH₄, GeF₄, GeHF₃, GeH₂F₂, GeH₃F₁, GeCl₄, GeHCl₃, GeH₂Cl₂, GeH₃Cl₁, GeBr₄, GeHBr₃, GeH₂Br₂, GeH₃Br₁, GeI₄, GeHI₃, GeH₂I₂, GeH₃I₁, GeF₂(C₄H₈O₂), GeCl₂(C₄H₈O₂), GeBr₂(C₄H₈O₂), GeI₂(C₄H₈O₂), GeH₂Me₂, GeH₂Et₂, GeH₂(i-Pr)₂, GeH(n-Bu)₃, Ge(NMe₂)₄, Ge(NMeEt)₄, Ge(NEt₂)₄, Ge[N(SiMe₃)₂]₄, Ge(NMe₂)₂[N(SiMe₃)₂]₂, Ge(NMe₂)₂[NH-Bu(CH₂)₂NHt-Bu], Ge[NH-Bu(CH₂)₂NH-Bu]₂, Ge(NMe₂)₂[NHi-Pr(CH₂)₂NHi-Pr], Ge[NHi-Pr(CH₂)₂NHi-Pr]2, Ge(OMe)₄, Ge(OEt)₄, Ge(Oi-Pr)₄, Ge(Ot-Bu)₄, or Ge(On-Bu)₄, GeN(CH₃)₂[(Ni—Pr)₂C═N—(CH₃)₂], Ge N(CH₃)₂[1,3,4,6,7,8-Hexahydro-2H-pyrimido[1,2-a]pyrimidine]; and preferably the germanium precursor is Ge(NMe₂)₄.

The subject matter of the present disclosure includes all novel and nonobvious combinations and sub combinations of the various processes, systems, and configurations, and other features, functions, acts, and/or properties disclosed herein, as well as any and all equivalents thereof.

The illustrations presented herein are not meant to be actual views of any particular material, structure, or device, but are merely idealized representations that are used to describe embodiments of the disclosure.

The particular implementations shown and described are illustrative of the disclosure and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

1. Method for forming a charge trapping layer of a memory element, comprising the steps of:
a) providing a substrate into a reaction chamber;
b) executing a plurality of cycles, a cycle comprising
i. a hafnium precursor pulse, wherein at least a part of said substrate is contacted with one or more hafnium precursor by introducing said one or more hafnium precursor in said reaction chamber;
ii. optionally, a zirconium precursor pulse, wherein at least a part of said substrate is contacted with one or more zirconium precursor by introducing said one or more zirconium precursor in said reaction chamber;
iii. an oxygen reactant pulse, wherein at least a part of said substrate is contacted with one or more oxygen reactant by introducing said one or more oxygen reactant into said reaction chamber;
iv. a germanium dopant pulse, wherein at least a part of said substrate is contacted with one or more germanium dopant by introducing said one or more germanium dopant into said reaction chamber; and
wherein, as a result of said plurality of cycles, a charge trapping layer comprising one or more germanium-doped hafnium zirconium oxide (HZO) film is formed on said substrate.

2. The method according to claim 1, wherein said one or more germanium dopant is represented by the following general formula (I) or (II), 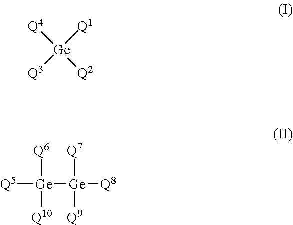
wherein Q¹, Q², Q³, Q⁴, Q⁵, Q⁶, Q⁷, Q⁸, Q⁹, Q¹⁰ are each independently chosen from the group consisting of hydrogen, halogen, alkyl, alkenyl, N(R¹)₂, (R²)₂NR³N(R⁴)₂, alkoxy, heteroalkyl, cycloalkoxy, cycloalkyl, aryl, and (R₆R₇N)(R₈R₉N)C═N—R₁₀; wherein each R¹, R², and R⁴ is independently hydrogen, alkyl, alkenyl, or Si(R⁵)₃; wherein each R³ is alkyl; and wherein each R⁵ is independently hydrogen, or alkyl; and wherein (R₆R₇N)(R₈R₉N)C═N—R₁₀ is 1,3,4,6,7,8-Hexahydro-2H-pyrimido[1,2-a]pyrimidine.

3. The method according to claim 2, wherein Q¹, Q², Q³, Q⁴, Q⁵, Q⁶, Q⁷, Q⁸, Q⁹, Q¹⁰ are each independently chosen from the group consisting of hydrogen, halogen, C₁₋₈alkyl, C₂₋₈alkenyl, N(R¹)₂, (R²)₂NR³N(R⁴)₂, C₁₋₈alkoxy, heteroC₁₋₈alkyl, C₃₋₈cycloalkoxy, C₃₋₈cycloalkyl, C₆₋₁₀aryl, (R₆R₇N)(R₈R₉N)C═N—R₁₀; wherein each R¹, R², and R⁴ is independently hydrogen, C₁₋₈alkyl, C₂₋₈alkenyl, or Si(R⁵)₃; wherein each R³ is C₁₋₈alkyl; wherein each R⁵ is independently hydrogen, or C₁₋₈alkyl; and wherein (R₆R₇N)(R₈R₉N)C═N—R₁₀ is 1,3,4,6,7,8-Hexahydro-2H-pyrimido[1,2-a]pyrimidine.

4. The method according to claim 2, wherein Q¹, Q², Q³, Q⁴, Q⁵, Q⁶, Q⁷, Q⁸, Q⁹, Q¹⁰ are each independently chosen from the group consisting of hydrogen, halogen, C₁₋₄alkyl, C₂₋₄alkenyl, N(R¹)₂, (R²)₂NR³N(R⁴)₂, C₁₋₄alkoxy, heteroC₁₋₄alkyl, C₃₋₈cycloalkoxy, C₃₋₈cycloalkyl, C₆₋₁₀aryl, (R₆R₇N)(R₈R₉N)C═N—R₁₀; wherein each R¹, R², and R⁴ is independently hydrogen, C₁₋₄alkyl, C₂₋₄alkenyl, or Si(R⁵)₃; wherein each R³ is C₁₋₄alkyl; wherein each R⁵ is independently hydrogen, or C₁₋₄alkyl; and wherein (R₆R₇N)(R₈R₉N)C═N—R₁₀ is 1,3,4,6,7,8-Hexahydro-2H-pyrimido[1,2-a]pyrimidine.

5. The method according to claim 1, wherein said one or more germanium dopant is chosen from the group consisting of Ge₂H₆, GeH₄, GeF₄, GeHF₃, GeH₂F₂, GeH₃F₁, GeCl₄, GeHCl₃, GeH₂Cl₂, GeH₃Cl₁, GeBr₄, GeHBr₃, GeH₂Br₂, GeH₃Br₁, GeI₄, GeHI₃, GeH₂I₂, GeH₃I₁, GeF₂(C₄H₈O₂), GeCl₂(C₄H₈O₂), GeBr₂(C₄H₈O₂), GeI₂(C₄H₈O₂), GeH₂Me₂, GeH₂Et₂, GeH₂(i-Pr)₂, GeH(n-Bu)₃, Ge(NMe₂)₄, Ge(NMeEt)₄, Ge(NEt₂)₄, Ge[N(SiMe₃)₂]₄, Ge(NMe₂)₂[N(SiMe₃)₂]₂, Ge(NMe₂)₂[NHt-Bu(CH₂)₂NHt-Bu], Ge[NHt-Bu(CH₂)₂NHt-Bu]₂, Ge(NMe₂)₂[NHi-Pr(CH₂)₂NHi-Pr], Ge[NHi-Pr(CH₂)₂NHi-Pr]₂, Ge(OMe)₄, Ge(OEt)₄, Ge(Oi-Pr)₄, Ge(Ot-Bu)₄, or Ge(On-Bu)₄, GeN(CH₃)₂[(Ni—Pr)₂C═N—(CH₃)₂], and GeN(CH₃)₂[1,3,4,6,7,8-Hexahydro-2H-pyrimido[1,2-a]pyrimidine].

6. The method according to claim 1, wherein said one or more germanium dopant is Ge(NMe₂)₄.

7. The method according to claim 1, wherein said one or more hafnium precursor is represented by the following general formula (III), 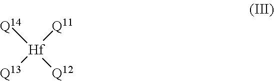
wherein Q¹¹, Q¹², Q¹³, Q⁴ are each independently chosen from the group consisting of halogen, alkyl, alkenyl, N(R¹)₂, alkoxy, heteroalkyl, cycloalkyl, aryl, and cyclopentadienyl, and wherein each R¹ is independently hydrogen, alkyl, or alkenyl.

8. The method according to claim 7, wherein Q¹¹, Q², Q³, Q⁴ are each independently chosen from the group consisting of halogen, C₁₋₈alkyl, C₂₋₈alkenyl, N(R¹)₂, C₁₋₈alkoxy, heteroC₁₋₈alkyl, C₃₋₈cycloalkyl, C₆₋₁₀aryl, and cyclopentadienyl, and wherein each R¹ is independently hydrogen, C₁₋₈alkyl, or C₂₋₈alkenyl.

9. The method according to claim 7, wherein Q¹¹, Q², Q³, Q⁴ are each independently chosen from the group consisting of halogen, C₁₋₄alkyl, C₂₋₄alkenyl, N(R¹)₂, C₁₋₄alkoxy, heteroC₁₋₄alkyl, C₃₋₈cycloalkyl, C₆₋₁₀aryl, and cyclopentadienyl, and wherein each R¹ is independently hydrogen, C₁₋₄alkyl, or C₂₋₄alkenyl.

10. The method according to claim 1, wherein said one or more hafnium precursor is chosen from the group consisting of HfCl₄, HfBr₄, HfI₄, HfMe₄, HfEt₄, Hf(nPr)₄, Hf(iPr)₄, Hf(nBu)₄, Hf(tBu)₄, Hf(NMe₂)₄, Hf(NEt₂)₄, Hf[MeEtN]₄, HfCp[(NMe₂)₃], Hf(OMe)₄, Hf(OEt)₄, Hf(OnPr)₄, Hf(OiPr)₄, Hf(OnBu)₄, Hf(OtBu)₄, Hf[(CpMe)₂][OMe][Me], Hf[(CpMe)₂][(Me)₂], Tetrakis(1-methoxy-2-methyl-2-propoxy)hafnium (Hf(mmp)₄).

11. The method according to claim 1, wherein said one or more zirconium precursor is represented by the following general formula (IV), 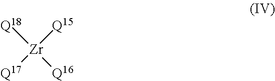
wherein Q¹⁵, Q¹⁶, Q¹⁷, Q¹⁸ are each independently chosen from the group consisting of halogen, alkyl, alkenyl, N(R¹)₂, alkoxy, heteroalkyl, cycloalkyl, aryl, and cyclopentadienyl, and wherein each R¹ is independently hydrogen, alkyl, or alkenyl.

12. The method according to claim 11, wherein Q¹⁵, Q¹⁶, Q¹⁷, Q¹⁸ are each independently chosen from the group consisting of halogen, C₁₋₈alkyl, C₂₋₈alkenyl, N(R¹)₂, C₁₋₈alkoxy, heteroC₁₋₈alkyl, C₃₋₈cycloalkyl, C₆₋₁₀aryl, and cyclopentadienyl, and wherein each R¹ is independently hydrogen, C₁₋₈alkyl, or C₂₋₈alkenyl.

13. The method according to claim 11, wherein Q¹⁵, Q¹⁶, Q¹⁷, Q¹⁸ are each independently chosen from the group consisting of halogen, C₁₋₄alkyl, C₂₋₄alkenyl, N(R¹)₂, C₁₋₄alkoxy, heteroC₁₋₄alkyl, C₃₋₈cycloalkyl, C₆₋₁₀aryl, and cyclopentadienyl, and wherein each R¹ is independently hydrogen, C₁₋₄alkyl, or C₂₋₄alkenyl.

14. The method according to claim 1, wherein said one or more zirconium precursor is chosen from the group consisting of ZrCl₄, ZrBr₄, ZrI₄, ZrMe₄, ZrEt₄, Zr(nPr)₄, Zr(iPr)₄, Zr(nBu)₄, Zr(tBu)₄, Zr(NMe₂)₄, Zr(NEt₂)₄, Zr[MeEtN]₄, ZrCp[(NMe₂)₃], Zr(OMe)₄, Zr(OEt)₄, Zr(OnPr)₄, Zr(OiPr)₄, Zr(OnBu)₄, Zr(OtBu)₄, Zr[(CpMe)₂][OMe][Me], Zr[(CpMe)₂][(Me)₂], Tetrakis(1-methoxy-2-methyl-2-propoxy)zirconium (Zr(mmp)₄).

15. The method according to claim 1, wherein said one or more oxygen reactant is chosen from the group consisting of H₂O, H₂O₂, O₃, O₂, O-containing plasma, N₂O, NO, N₂O₅, and oxygen radicals.

16. The method according to claim 1, wherein said substrate comprises silicon, silicon germanium, silicon oxide, gallium arsenide, gallium nitride or silicon carbide.

17. The method according to claim 1, wherein said substrate is heated to a temperature of about 80° C. to about 400° C.

18. The method according to claim 1, wherein pressure in said reaction chamber is between about 0.1 Torr and about 100.0 Torr.

19. The method according to claim 1, wherein an oxygen reactant pulse is carried out after each hafnium precursor pulse and/or after each zirconium precursor pulse.

20. The method according to claim 19, wherein said germanium dopant pulse is carried out after said hafnium precursor pulse without any intervening oxygen reactant pulse.
